(19) United States
(12) Patent Application Publication
(10) Pub. No.: US 2024/0061402 A1
(43) Pub. Date: Feb. 22, 2024

(54) MANAGEMENT SYSTEM, MANAGEMENT DEVICE, MANAGEMENT METHOD, AND PROGRAM

(71) Applicant: OMRON Corporation, Kyoto-shi, KYOTO (JP)

(72) Inventors: Hiroyuki MORI, Kyoto-shi, KYOTO (JP); Mayuko TANAKA, Kyoto-shi, KYOTO (JP); Isao NAKANISHI, Kyoto-shi, KYOTO (JP); Katsuki NAKAJIMA, Kyoto-shi, KYOTO (JP)

(21) Appl. No.: 18/259,757

(22) PCT Filed: Mar. 8, 2021
(86) PCT No.: PCT/JP2021/009044

§ 371 Date: Jun. 28, 2023

(30) Foreign Application Priority Data
Jan. 22, 2021 (JP) 2021-008773

(51) Int. Cl. G05B 19/4155

(52) U.S. Cl. CPC G05B 19/4155; G05B 2219/31372

(57) ABSTRACT

A management system includes a production data obtainer that obtains production data being information including a production condition for a product, an optimal value calculator that calculates, based on the production data, an optimal production condition being a production condition optimal to produce the product, an optimal value setting determiner that performs determination as to whether the optimal production condition is to be set as a renewed production condition for the production facility, and an optimal value setter that sets the optimal production condition for the production facility under a predetermined condition. The optimal value setting determiner determines that the optimal production condition is to be set as the renewed production condition for the production facility in response to the production condition at a time of the determination being identical to the production condition used to calculate the optimal production condition by the optimal value calculator.

### FIELD

The present invention relates to a technique for quality control and process improvement in a production line.

### BACKGROUND

An automated, labor-saving production line includes an intermediate process or a final process in which an inspection apparatus is installed to, for example, automatically detect defects or sort defective products. The results of inspection performed by such inspection apparatuses are used to determine the causes of defects for effective quality control and effective maintenance of a production facility.

For example, a production line for component mounting boards typically includes a process for printing cream solder on a wiring board (printing), a process for mounting components on the printed board (mounting), and a process for heating the printed board with mounted components to solder the components to the board (reflowing), after each of which the board is inspected.

In the production line with the above structure, a known system calculates an optimal inspection criterion for optimizing inspection for each process based on information resulting from inspection after each process, and feeds the calculated criterion back to the corresponding inspection apparatus (e.g., Patent Literatures 1 and 2). Another known system creates correction information to correct a manufacturing program (or parameters) for a component manufacturing apparatus for each process based on information resulting from inspection after each process, and feeds the correction information back to the manufacturing apparatus.

For example, Patent Literatures 1 and 2 describe calculating an optimal inspection criterion for a process using the result of inspection after the process, presenting, to the user, the basis for the calculated optimal inspection criterion, and setting the calculated inspection criterion for an inspection apparatus after the user's approval.

Patent Literature 3 describes detecting, by inspection after a mounting process, inspection information including the degrees of misalignment of components mounted on a board, calculating correction values based on the detected degrees of misalignment to correct the positions on the board at which the components are to be mounted by a component mounting apparatus, and correcting, with the component mounting apparatus, the mounting positions based on the correction values.

Patent Literature 4 describes changing parameters (the temperature profile of a reflow oven) for fixing components to a board in a reflow process when the result of inspection after a mounting process indicates no abnormal misalignment of the components on the board and when the result of inspection after a reflow process indicates abnormal misalignment of the components.

As described above, the optimal manufacturing condition or the optimal inspection criterion is automatically calculated based on the inspection result and actually set for the manufacturing apparatus or the inspection apparatus. This effectively reduces defects and false acceptance of defects in the production line and reduces overdetection (false rejection) in inspection.

### CITATION LIST

### Patent Literature

Patent Literature 1: Japanese Unexamined Patent Application Publication No. 2019-125693
Patent Literature 2: Japanese Unexamined Patent Application Publication No. 2019-125694
Patent Literature 3: Japanese Unexamined Patent Application Publication No. 2018-056447
Patent Literature 4: Japanese Unexamined Patent Application Publication No. 2020-043159

### SUMMARY

### Technical Problem

Although a manufacturing parameter or another factor of a manufacturing apparatus (hereafter, a manufacturing condition) or an inspection criterion for an inspection apparatus is optimized based on information about the result of inspection after each process, the apparatus can have lower manufacturing efficiency or lower inspection efficiency using the optimized manufacturing condition or the optimized inspection criterion.

More specifically, for example, the manufacturing condition used when an optimal manufacturing condition is set for the manufacturing apparatus may differ from the manufacturing condition used to calculate the optimal manufacturing condition. This changes the reference used in optimization, thus producing unintended effects or opposite effects.

For an inspection apparatus as well, any change in conditions other than the inspection criterion (e.g., a parameter for extracting inspection coordinates or an inspection target) can change a measurement value. In this case, the optimal inspection criterion calculated using the measurement value before the change in conditions may no longer be appropriate when the optimal inspection criterion is set for the inspection apparatus.

In response to the above, one or more aspects of the present invention are directed to a technique for increasing the efficiency of facility maintenance and quality control in a production facility.

### Solution to Problem

The technique according to one or more aspects of the present invention provides the structure described below. A management system for a production facility to produce a product includes a production data obtainer that obtains production data being information including a production condition for the product, an optimal value calculator that calculates, based on the production data, an optimal production condition being a production condition optimal to produce the product, an optimal value setting determiner that performs determination as to whether the optimal production condition is to be set as a renewed production condition for the production facility, and an optimal value setter that sets the optimal production condition for the production facility under a predetermined condition. The optimal value setting determiner determines that the optimal production condition is to be set as the renewed production condition for the production facility in response to the production condition at a time of the determination being identical to the production condition used to calculate the optimal production condition by the optimal value calculator.

The production facility herein refers to any facility for producing a product, such as a manufacturing apparatus, an inspection apparatus, or a combination of these apparatuses (or in other words, a group of multiple apparatuses). The production condition herein may be any of various recipes, parameters, or criteria for producing a product, such as a parameter used for the manufacturing apparatus, or an inspection condition (including any of various inspection criteria) used for the inspection apparatus. The production data herein may include the name of an information processing program executable at each production facility and its revision. The setting herein may be changing. The product herein may be an intermediate product or a finished product.

The inspection system with the above structure prevents setting of the calculated optimal production condition when the production condition used to calculate the optimal production condition (e.g., the manufacturing condition or the inspection criterion) differs from the production condition currently set for the facility. This prevents an unintended change in the production condition when the optimal production condition is not to be reflected (or in other words, when the optimality of the condition is undetermined). This allows more efficient maintenance of the production facility without lowering the product quality.

The optimal value setter may set the optimal production condition for the production facility in response to the optimal value setting determiner determining that the optimal production condition is to be set as the renewed production condition.

This structure can automatically reflect the optimal production condition in each production facility in response to the optimal value setting determiner determining that the optimal production condition is to be set as the renewed production condition. This can reduce the work-hours for setting the production condition and increase the efficiency of the production facility.

The management system may further include an output device that outputs at least a result of the determination, and an input device. The optimal value setter may set the optimal production condition for the production facility in response to receiving, with the input device, an instruction to reflect the optimal production condition in the production facility.

This structure allows the manager of the production facility to refer to the result of determination performed by the optimal value setting determiner, and then to determine whether the optimal production condition is to be actually reflected. This allows, for example, the manager to flexibly set the optimal production condition as intended independently of whether the production condition used to calculate the optimal production condition is identical to or different from the currently set production condition.

The management system may further include an optimal value setting obtainer that obtains information about whether the optimal production condition is set for the production facility. This structure can obtain information about whether the optimal production condition has been set for the production facility and information about the time at which the optimal production condition is set. This allows determination as to whether the facility has been improved through the process.

The production data may include information identifying a revision of a production program for information processing to operate the production facility. The optimal value setting determiner may determine, in response to the revision of the production program at the time of the determination being identical to the revision of the production program used to calculate the optimal production condition by the optimal value calculator, that the production condition at the time of the determination is identical to the production condition used to calculate the optimal production condition by the optimal value calculator, and determine that the optimal production condition is to be set as the renewed production condition for the production facility.

The production program for information processing to operate the production facility herein includes a program executable at each production facility (e.g., a manufacturing apparatus or an inspection apparatus). The information identifying the revision of the production program herein may be, for example, the name of a manufacturing program executable at the manufacturing apparatus and its revision, or the name of an inspection program executable at the inspection apparatus and its revision.

The production data may include product element information about a product element included in the product, and a revision of the product element information. The information identifying the revision of the production program may include the revision of the product element information.

The product element herein refers to an element included in a product. For a component mounting board, for example, a product element may be an electronic product element such as an integrated circuit (IC) chip, a printed circuit board (bare board), or solder. The product element information herein refers to information about the product element, such as data (e.g., a component number library) managed for, for example, each component number, each group of components with different component numbers satisfying a predetermined condition (e.g., components with the same shape or with the same use), or each group of components satisfying a specific condition (e.g., components to be mounted in a specific portion). The product element information may include the reel identification (ID), the production lot of a product element, the type of a product element, the shape of a product element, and the position of a product element on the board. The revision of product element information herein refers to a revision of information about, for example, the component number, the group of components with different component numbers satisfying a predetermined condition, or the group of components satisfying a specific condition.

The revision of product element information managed outside the production program may differ between when the optimal value is calculated and when the optimal value is determined to be or not to be set, without any change in the revision of the production program. In this situation, the above structure can prevent the renewed production condition from being unintentionally set.

The production data may include product element information about a product element included in the product, and information about a revision of the product element information. The optimal value setting determiner may determine, in response to the revision of the product element information about a specific product element in the product at the time of the determination being identical to the revision of the product element information about the specific product element in the product used to calculate the optimal production condition by the optimal value calculator, that the production condition at the time of the determination is identical to the production condition used to calculate the optimal production condition by the optimal value calculator, and determine that the optimal production condition is to be set as the renewed production condition for the production facility.

This allows determination as to whether the production condition used to calculate the optimal value is identical to the currently set production condition for each individual production element (or for each individual group of production elements) in the product. In other words, when the optimal production condition is calculated for a specific product element, the production condition for the specific product element can be set independently of any change in the revision of the production program and without affecting the production condition for another product element.

The production facility may include a manufacturing apparatus that manufactures the product. The production data obtained by the production data obtainer may include manufacturing data being information including a manufacturing condition to manufacture the product with the manufacturing apparatus. The optimal value calculator may calculate at least an optimal manufacturing condition being a manufacturing condition optimal for manufacturing the product. The optimal value setting determiner may determine that the optimal manufacturing condition is to be set as a renewed manufacturing condition for the manufacturing apparatus in response to at least the manufacturing condition at the time of the determination being identical to the manufacturing condition used to calculate the optimal manufacturing condition by the optimal value calculator. The optimal value setter may set the optimal manufacturing condition for the manufacturing apparatus under the predetermined condition.

The manufacturing apparatus herein refers to any of various apparatuses that manufacture products, such as an apparatus in the production line for component mounting boards (e.g., solder printers, mounters, or reflow ovens), a manufacturing apparatus for various product elements included in boards, or a manufacturing apparatus for solder. The manufacturing condition herein may be, for example, any of various mounting parameters for solder printers, mounters, or reflow ovens in a production line for component mounting boards. For a mounter, for example, the mounting parameters include component pickup coordinates, mounting coordinates, shape models for components, and component sizes. More specifically, the mounting parameters may include board piece numbers, circuit numbers, and component numbers. The manufacturing data herein may include information about any of various product elements used at the manufacturing apparatus, any of various apparatus elements included in the manufacturing apparatus, or an error detected during manufacturing. The manufacturing data may also include the name of a mounting program executable at the manufacturing apparatus and its revision. The manufacturing data may also include product element information used for the mounting program and its revision. The product element information may be managed outside the manufacturing program.

The structure prevents setting of the calculated optimal manufacturing condition when the manufacturing condition used to calculate the optimal manufacturing condition differs from the currently set manufacturing condition.

The production facility may include an inspection apparatus that performs inspection of the product. The production data obtained by the production data obtainer may include inspection data including an inspection condition for the inspection, and inspection result data being information about a result of the inspection. The optimal value calculator may calculate at least an optimal inspection criterion being an inspection criterion optimal for the inspection. The optimal value setting determiner may determine that the optimal inspection criterion is to be set as a renewed inspection criterion for the inspection apparatus in response to at least the inspection condition at the time of the determination being identical to the inspection condition used to calculate the optimal inspection criterion by the optimal value calculator. The optimal value setter may set the optimal inspection criterion for the inspection apparatus under the predetermined condition.

The inspection apparatus herein refers to an apparatus that performs inspection, such as solder paste inspection (SPI), automated optical inspection (AOI), or automated X-ray inspection (AXI). The inspection apparatus may reflect information resulting from visual inspection. The inspection apparatus may be built in the manufacturing apparatus. The inspection condition herein may be an inspection item for each product, an inspection criterion for the inspection item (e.g., a threshold for determining whether a product is acceptable), a parameter for extracting inspection coordinates or an inspection target, or a process for determining whether to perform inspection with the inspection criterion for each item. The inspection data herein may include the name of an inspection program executable at the inspection apparatus and its revision. The inspection data may also include product element information used for the inspection program and its revision. The product element information may be managed outside the inspection program. The inspection result data herein includes a determination result as to whether the product is acceptable, and also includes a measurement value of an inspection target measured in inspection.

The structure prevents setting of the calculated optimal inspection criterion when the inspection condition used to calculate the optimal inspection criterion differs from the currently set inspection condition.

The production facility may include a manufacturing apparatus that manufactures the product, and an inspection apparatus that performs inspection of the product. The production data obtained by the production data obtainer may include manufacturing data being information including a manufacturing condition to manufacture the product with the manufacturing apparatus, inspection data including an inspection condition for the inspection, and inspection result data being information about a result of the inspection. The optimal value calculator may calculate, based on the manufacturing data, the inspection data, and the inspection result data, at least an optimal manufacturing condition being a manufacturing condition optimal for manufacturing the product. The optimal value setting determiner may determine that the optimal manufacturing condition is to be set as a renewed manufacturing condition for the manufacturing apparatus in response to the manufacturing condition and the inspection condition used to calculate the optimal manufacturing condition by the optimal value calculator being identical to the manufacturing condition and the inspection condition at the time of the determination. The optimal value setter may set the optimal manufacturing condition for the manufacturing apparatus under the predetermined condition.

When the optimal manufacturing condition is to be set for the manufacturing apparatus, the inspection condition for the inspection apparatus at the setting may differ from the inspection condition used to calculate the optimal manufacturing condition. For example, the inspection criterion can be changed to be stricter for higher product quality or to be more lenient (specifically, with greater tolerance for uneven quality) for a higher production rate. The optimal manufacturing condition calculated based on the inspection result at the inspection apparatus may be no longer optimal when the optimal manufacturing condition is set for the manufacturing apparatus. In this situation, the above structure can prevent an unintended change in the manufacturing condition.

The optimal value calculator may calculate, based on the manufacturing data, the inspection data, and the inspection result data, at least an optimal inspection criterion being an inspection criterion optimal for the inspection. The optimal value setting determiner may determine that the optimal inspection criterion is to be set as a renewed inspection criterion for the inspection apparatus in response to the manufacturing condition and the inspection condition used to calculate the optimal inspection criterion by the optimal value calculator being identical to the manufacturing condition and the inspection condition at the time of the determination. The optimal value setter may set the optimal inspection criterion for the inspection apparatus under the predetermined condition.

When the optimal inspection criterion is used by the inspection apparatus, the manufacturing condition for the manufacturing apparatus at the setting may differ from the manufacturing condition used to calculate the optimal inspection criterion. For example, the manufacturing condition can be changed for a higher level of the product. The optimal inspection criterion calculated based on the level of the product manufactured by the manufacturing apparatus may be no longer optimal when the optimal inspection criterion is set for the inspection apparatus. In this situation, the above structure can prevent an unintended change in the inspection criterion.

Another aspect of the present invention may also be directed to a management apparatus in a production facility to produce a product. The management apparatus includes a production data obtainer that obtains production data being information including a production condition for the product, an optimal value calculator that calculates, based on the production data, an optimal production condition being a production condition optimal to produce the product, an optimal value setting determiner that performs determination as to whether the optimal production condition is to be set as a renewed production condition for the production facility, and an optimal value setter that sets the optimal production condition for the production facility under a predetermined condition. The optimal value setting determiner determines that the optimal production condition is to be set as the renewed production condition for the production facility in response to the production condition at a time of the determination being identical to the production condition used to calculate the optimal production condition by the optimal value calculator.

Another aspect of the present invention may also be directed to a management method for a production facility to produce a product. The management method includes obtaining production data being information including a production condition for the product, calculating, based on the production data, an optimal production condition being a production condition optimal to produce the product, performing determination as to whether the optimal production condition is to be set as a renewed production condition for the production facility, and setting the optimal production condition for the production facility under a predetermined condition. Performing the determination includes determining that the optimal production condition is to be set as the renewed production condition for the production facility in response to the production condition at a time of the determination being identical to the production condition used to calculate the optimal production condition.

One or more aspects of the present invention may also be directed to a program for causing a computer to implement the method described above, or to a non-transitory computer-readable storage medium storing the program. The above structures and processes may be combined with one another unless any technical contradiction arises.

### Advantageous Effects

The technique according to the above aspects of the present invention increases the efficiency of the facility maintenance and the quality control in the production facility.

### BRIEF DESCRIPTION OF THE DRAWINGS

FIG. 1 is a block diagram of a production facility management system in an example use.

FIG. 2 is a flowchart of processing performed by the production facility management system in the example use.

FIG. 3 is a schematic diagram of a production facility management system according to an embodiment.

FIG. 4 is a functional block diagram of the production facility management system according to the embodiment.

FIG. 5 is a flowchart of processing performed by the production facility management system according to the embodiment.

FIG. 6 is a block diagram of a production facility management system according to a modification of the embodiment.

### DETAILED DESCRIPTION

Embodiments of the present invention will now be described with reference to the drawings. The dimensions, materials, shapes, and relative positions of the components described in the embodiments do not intend to limit the scope of the present invention, unless otherwise specified.

<Example Use>

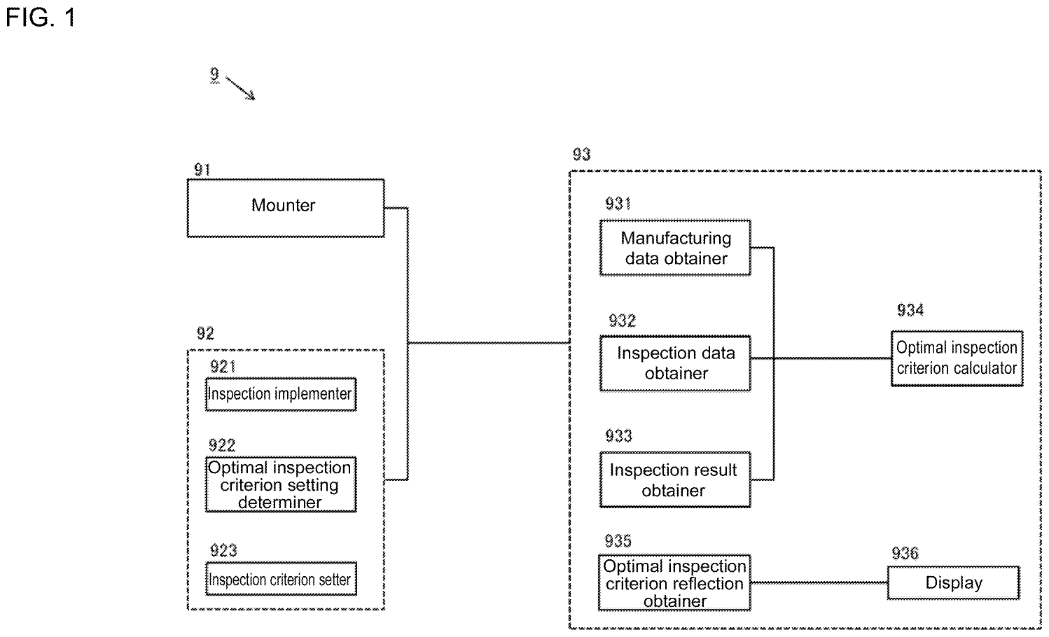

A production facility management system 9 according to one or more embodiments of the present invention is shown in FIG. 1. The production facility management system 9 manages a chip mounter (hereafter, simply a mounter) in a surface mounting line for printed circuit boards. The production facility management system 9 includes, as its components, a mounter 91, a mount inspection apparatus 92, and a management apparatus 93. These components are interconnected with a network such as a local area network (LAN).

The mounter 91 picks up an electronic component to be mounted on the board and mounts the component on the solder paste on the target portion.

The mount inspection apparatus 92 inspects the placement of an electronic component on the board unloaded from the mounter 91. As shown in FIG. 1, the mount inspection apparatus 92 includes, as functional modules, an inspection implementer 921, an optimal inspection criterion setting determiner 922, and an inspection criterion setter 923. The inspection implementer 921 measures, two- or three-dimensionally, the placement of the component (the component body or a part of the component such as an electrode) mounted on the solder paste, and determines whether the measurement values fall within the range of normal values (tolerances) for various inspection items. The functions of the optimal inspection criterion setting determiner 922 and the inspection criterion setter 923 are described later.

Although not shown, the management apparatus 93 includes a general-purpose computer system including a central processing unit (CPU or processor), a main storage (memory), an auxiliary storage (e.g., a hard disk drive), input devices (e.g., a keyboard, a mouse, a controller, and a touch screen), and output devices (e.g., a display, a printer, and a speaker).

As shown in FIG. 1, the management apparatus 93 includes, as functional modules, a manufacturing data obtainer 931, an inspection data obtainer 932, an inspection result obtainer 933, an optimal inspection criterion calculator 934, an optimal inspection criterion reflection obtainer 935, and a display 936. Each functional module may be implemented by, for example, the CPU reading and executing a program stored in a storage.

The manufacturing data obtainer 931 obtains information about manufacturing details (hereafter, manufacturing data), including information about components (e.g., various electronic components, a board, and solder) used at the mounter 91, various mounting parameters (e.g., component pickup coordinates, mounting coordinates, shape models for components, and component sizes), and the name of a mounting program executable at the mounter 91 and its revision. The information to be obtained herein may include information about the apparatus elements included in the mounter 91 or information about errors detected during the mounting process.

The inspection data obtainer 932 obtains information about inspection details (hereafter, inspection data), including an inspection item for the mount inspection apparatus 92, the inspection criterion for the inspection item (e.g., a threshold for determining whether the product is acceptable), a parameter for extracting inspection coordinates or an inspection target, and the name of an inspection program executable at the mount inspection apparatus 92 and its revision.

The inspection result obtainer 933 obtains information about the result of inspection performed by the mount inspection apparatus 92 (hereafter, inspection result data). The result of inspection herein includes the result of determination as to whether the product is acceptable, and also includes information about the measurement value of each component.

The optimal inspection criterion calculator 934 calculates the optimal inspection criterion based on information obtained by the manufacturing data obtainer 931, the inspection data obtainer 932, and the inspection result obtainer 933. More specifically, for example, the optimal inspection criterion calculator 934 calculates, through an inspection simulation, an inspection criterion that allows less false acceptance of defects or less overdetection (false rejection) than the current inspection criterion. When such an inspection criterion cannot be calculated, the current inspection criterion is determined to be the optimal inspection criterion.

The display 936 is, for example, a liquid crystal display and outputs (displays) information obtained by the optimal inspection criterion reflection obtainer 935 (described later).

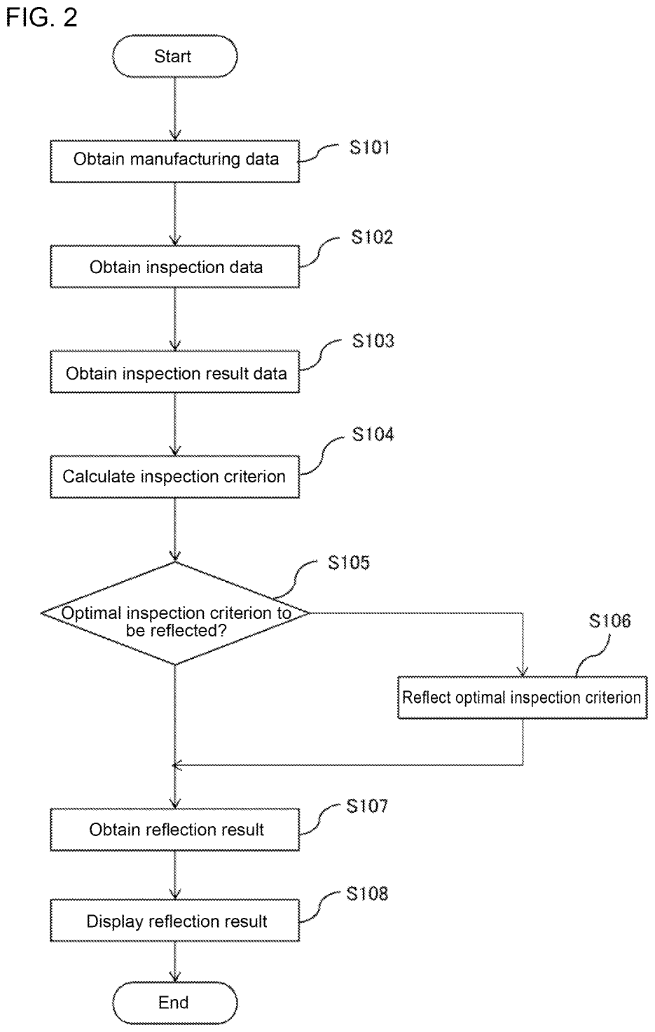

The processing for setting the optimal inspection criterion in the production facility management system 9 will now be described with reference to FIG. 2. In response to a user instruction or at a predetermined timing, for example, the management apparatus 93 obtains manufacturing data with the manufacturing data obtainer 931 (S101), obtains inspection data with the inspection data obtainer 932 (S102), and obtains inspection result data with the inspection result obtainer 933 (S103).

The management apparatus 93 then calculates the optimal inspection criterion with the optimal inspection criterion calculator 934, and transmits, to the inspection apparatus, the calculated optimal inspection criterion and information identifying the inspection condition (including the inspection criterion) used to calculate the optimal inspection criterion (S104). Information identifying the inspection condition used to calculate the optimal inspection criterion herein may be, for example, the name of the inspection program and its revision. The information may identify an inspection criterion managed outside the inspection program (e.g., a revision of a component number library).

The mount inspection apparatus 92 then determines, with the optimal inspection criterion setting determiner 922, whether the calculated optimal inspection criterion is to be set as the renewed inspection criterion for the mount inspection apparatus 92 (S105). More specifically, the mount inspection apparatus 92 may determine whether the inspection condition currently set for the inspection apparatus is identical to the inspection condition used to calculate the inspection criterion transmitted in step S104. For example, the information identifying the inspection condition used to calculate the optimal inspection criterion may be the name of an inspection program and its revision. In this case, the revision of the inspection program currently set for the inspection apparatus may be referred to for determining whether both the revisions are identical to each other. In another example, the information identifying the inspection condition used to calculate the optimal inspection criterion may be a revision of a component number library identifying the inspection criterion managed outside the inspection program. In this case, the revision of the component number library accessed by the inspection program may be referred to.

When the mount inspection apparatus 92 determines that the optimal inspection criterion is not to be set as the renewed inspection criterion in step S105, such information is transmitted to the management apparatus 93, and the processing advances to step S107. In this case, the inspection condition used to calculate the optimal inspection criterion has changed. Thus, setting the inspection criterion calculated in step S104 for the mount inspection apparatus 92 can produce no effects or possibly produce opposite effects. Thus, the inspection criterion is not set (changed).

When the mount inspection apparatus 92 determines that the optimal inspection criterion is to be set as the renewed inspection criterion in step S105, the mount inspection apparatus 92 sets, with the inspection criterion setter 923, the optimal inspection condition calculated in step S104 as the renewed inspection criterion for the mount inspection apparatus 92, and transmits such information to the management apparatus 93 (S106). The processing then advances to step S107.

The management apparatus 93 then obtains, with the optimal inspection criterion reflection obtainer 935, information about whether the inspection criterion calculated in step S104 has been reflected in the mount inspection apparatus 92 (S107), displays the information on the display 936 (S108), and ends the processing.

When the inspection criterion for the inspection apparatus is changed in step S106, the display 936 may display information indicating that the inspection criterion for the mount inspection apparatus 92 has been updated to the optimal inspection criterion. When the mount inspection apparatus 92 determines, in step S105, that the inspection condition currently set for the inspection apparatus is not identical to the inspection condition used to calculate the optimal inspection criterion, such information may be displayed together with an interface screen to receive a user instruction about whether the inspection criterion calculated in step S104 is to be set as the renewed inspection criterion for the mount inspection apparatus 92.

As described above, the production facility management system 9 in the example use can calculate the optimal inspection criterion for the mount inspection apparatus 92 installed in the production line, and automatically determine whether the optimized inspection criterion is appropriate as the renewed inspection criterion for the mount inspection apparatus 92. When determining that the optimized inspection criterion is appropriate as the renewed inspection criterion, the system automatically sets the optimized inspection criterion for the mount inspection apparatus 92. When determining that the optimized inspection criterion is inappropriate, the system does not use the optimized inspection criterion (or suspends its determination about setting the optimized inspection criterion). This allows automatic optimization of the inspection criterion without unintended setting of an inappropriate inspection criterion for the mount inspection apparatus 92.

### EMBODIMENTS

One embodiment of the present invention will now be described in more detail.

(System Configuration)

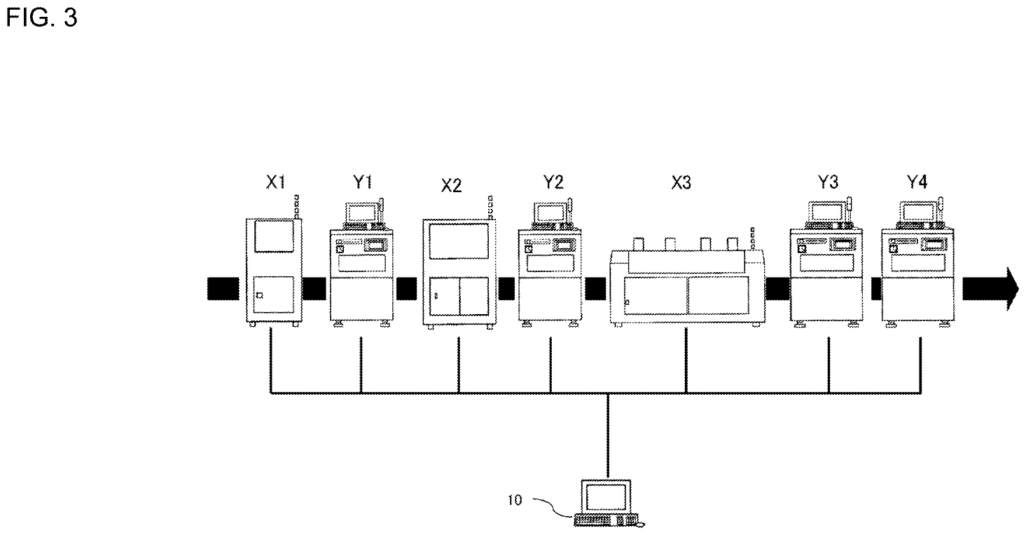

FIG. 3 is a schematic diagram of a production facility management system 1 in a surface mounting line for printed circuit boards according to an embodiment. Surface mount technology (SMT) is a technique for soldering an electronic component on a surface of a printed board and includes three main processes including solder printing, component mounting, and reflowing (solder melting).

The surface mounting line includes, as manufacturing apparatuses, a solder printer X1, a mounter X2, and a reflow oven X3 in order from upstream as shown in FIG. 3. The solder printer X1 prints a solder paste on electrodes (or lands) on a printed board by screen printing. The mounter X2, or a chip mounter, picks up an electronic component to be mounted on the board and mounts the component on the solder paste on the target portion. The reflow oven X3 heats and melts the solder paste, and then cools the solder paste to solder the electronic component on the board. The surface mounting line may include multiple mounters X2 when a large number of or various electronic components are to be mounted on the board. As described later, each of the solder printer X1, the mounter X2, and the reflow oven X3 includes, as functional units, a manufacturing implementer, a determiner, and a manufacturing condition setter. The functions will be described later.

The solder printing inspection apparatus Y1 inspects the state of the solder paste printed on the board unloaded from the solder printer X1. The solder printing inspection apparatus Y1 measures, two- or three-dimensionally, the solder paste printed on the board, and determines whether the measurement values fall within the range of normal values (tolerances) for various inspection items. The inspection items include the volume, surface area, height, positional deviation, and shape of the solder. The solder paste is measured two-dimensionally with, for example, an image sensor (camera), and three-dimensionally with, for example, a laser shift meter, a phase shifting method, a space-coding method, or a light-section method.

The mount inspection apparatus Y2 inspects the placement of an electronic component on the board unloaded from the mounter X2. The mount inspection apparatus Y2 measures, two- or three-dimensionally, the component (the component body or a part of the component such as an electrode) mounted on the solder paste, and determines whether the measurement values fall within the range of normal values (tolerances) for various inspection items. The inspection items include the positional deviation or angular (rotational) deviation of a component, a missing component (no component being placed), a component mix-up (a different component being placed), different polarities (the polarity of the component different from the polarity of the board), reversal of a component (a component being placed upside down), and the height of a component. As in the solder printing inspection, the electronic component is measured two-dimensionally with, for example, an image sensor (camera), and three-dimensionally with, for example, a laser shift meter, a phase shifting method, a space-coding method, or a light-section method.

The visual inspection apparatus Y3 inspects the condition of a solder joint on the board unloaded from the reflow oven X3. The visual inspection apparatus Y3 measures the post-reflowing solder two- or three-dimensionally, and determines whether the measurement values fall within the range of normal values (tolerances) for various inspection items. The inspection items include the shape of a solder fillet, in addition to the items used in the component inspection. The shape of solder is determined with, for example, a laser shift meter, a phase shifting method, a space-coding method, or a light-section method as described above, or also with a color highlight method (a method for determining the three-dimensional shape of solder with two-dimensional hue information by illuminating the solder surface with RGB color light at different angles of incidence and capturing the reflected light of each color using a top camera).

The X-ray inspection apparatus Y4 inspects the state of a solder joint on the board using an X-ray image. For example, a multilayer board or a package component, such as a ball grid array (BGA) and a chip size package (CSP), has solder joints hidden under the board or the component. In this structure, the state of the solder cannot be inspected with the visual inspection apparatus Y3 (or with an image of the product appearance). The X-ray inspection apparatus Y4 overcomes such weakness of visual inspection. The inspection items for the X-ray inspection apparatus Y4 include the positional deviation of a component, the height of solder, the volume of solder, the diameter of a solder ball, the length of a back fillet, and the condition of a solder joint. The X-ray image may be an image produced by projecting X-rays or an image produced using the computed tomography (CT) scan.

As described later, each of the inspection apparatuses Y1, Y2, Y3, and Y4 includes, as functional units, an inspection implementer, a determiner, and an inspection criterion setter. The functions will be described later.

(Management Apparatus)

The manufacturing apparatuses X1, X2, and X3 and the inspection apparatuses Y1, Y2, Y3, and Y4 described above are connected to a management apparatus 10 with a network (LAN). The management apparatus 10 is a system for managing and controlling the manufacturing apparatuses X1, X2, and X3 and the inspection apparatuses Y1, Y2, Y3, and Y4, and includes, although not shown, a general-purpose computer system including a CPU or processor, a main storage (memory), an auxiliary storage (e.g., a hard disk drive), input devices (e.g., a keyboard, a mouse, a controller, and a touch screen), and a display device. The functions of the management apparatus 10 described below are implemented by the CPU reading programs stored in the auxiliary storage and executing the programs.

The management apparatus 10 may include a single computer or multiple computers. All or some of the functions of the management apparatus 10 may be implemented by a computer in any of the manufacturing apparatuses X1, X2, or X3 or the inspection apparatuses Y1, Y2, Y3, or Y4. Some of the functions of the management apparatus 10 may be implemented by a server on a network (e.g., a cloud server).

(Functional Units)

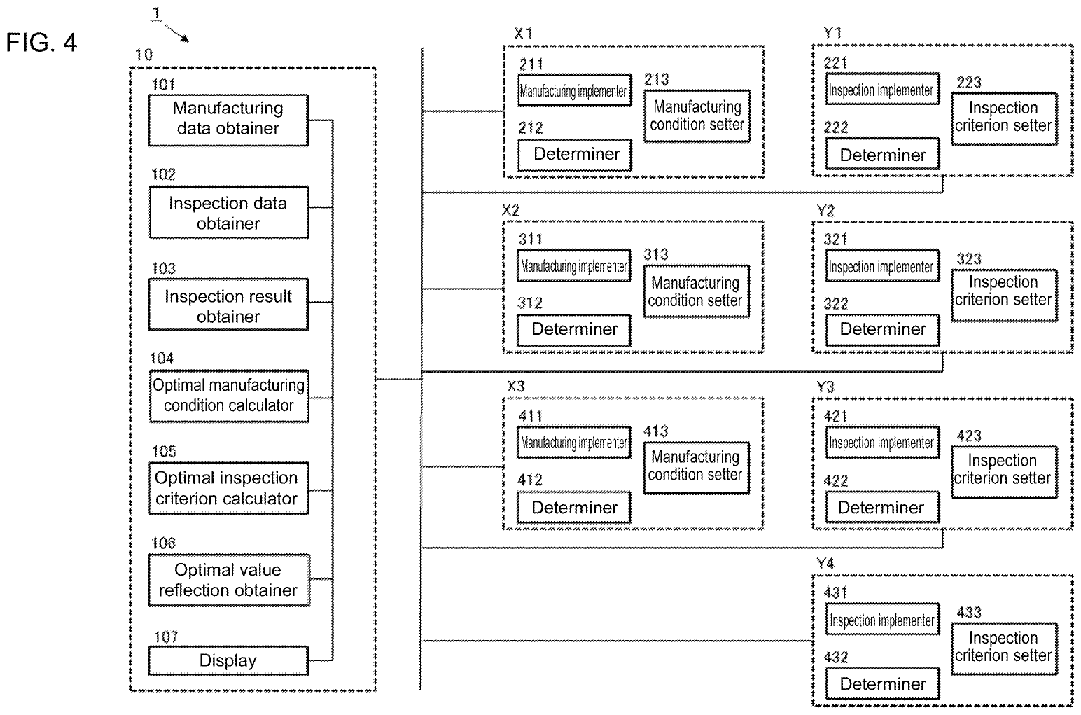

The production facility management system 1 according to the present embodiment allows the manager of the production facility to perform efficient facility maintenance and efficient quality control. FIG. 4 is a functional block diagram of the management apparatus 10, the manufacturing apparatuses X1, X2, and X3, and the inspection apparatuses Y1, Y2, Y3, and Y4.

As shown in FIG. 4, the management apparatus 10 includes, as functional units, a manufacturing data obtainer 101, an inspection data obtainer 102, an inspection result obtainer 103, an optimal manufacturing condition calculator 104, an optimal inspection criterion calculator 105, an optimal value reflection obtainer 106, and a display 107.

The manufacturing data obtainer 101 obtains information about manufacturing details (hereafter, manufacturing data), including information about components (e.g., various electronic components, a board, and solder) used at each of the solder printer X1, the mounter X2, and the reflow oven X3, various mounting (manufacturing) parameters, and the name of a manufacturing program executable at each manufacturing apparatus and its revision. The information to be obtained herein may include information about the apparatus elements included in each of the manufacturing apparatuses X1, X2, and X3 or information about errors detected during the mounting process.

The manufacturing data obtainer 101 obtains information about inspection details (hereafter, inspection data), including an inspection item for each of the inspection apparatuses Y1, Y2, Y3, and Y4, the inspection criterion for the inspection item (e.g., a threshold for determining whether the product is acceptable), a parameter for extracting inspection coordinates or an inspection target, and the name of an inspection program executable at each of the inspection apparatuses Y1, Y2, Y3, and Y4 and its revision.

The inspection result obtainer 103 obtains information about the result of inspection performed by each of the inspection apparatuses Y1, Y2, Y3, and Y4 (hereafter, inspection result data). The result of inspection herein includes the result of determination as to whether the product is acceptable, and also includes information about the measurement value of each component.

The optimal manufacturing condition calculator 104 calculates the optimal manufacturing condition for each of the manufacturing apparatuses X1, X2, and X3 based on the manufacturing data, inspection data, and inspection result data. More specifically, the optimal manufacturing condition calculator 104 calculates the condition with various parameters optimized for each of the manufacturing apparatuses X1, X2, and X3 based on, for example, information about errors and inspection results at the corresponding manufacturing apparatus.

The optimal manufacturing condition calculated in this manner is transmitted to the target manufacturing apparatus using a communicator (not shown), together with information (e.g., the name of the manufacturing program and its revision) identifying the manufacturing condition used to calculate the optimal manufacturing condition. The target manufacturing apparatus then determines whether to set the transmitted condition, as described later.

The manufacturing condition to be transmitted herein may include all the information about the manufacturing condition, or may be information specifying simply a change (a parameter item, a changed portion, or changed details) in the manufacturing condition used to calculate the optimal manufacturing condition. The manufacturing condition used to calculate the optimal manufacturing condition may also be transmitted.

For example, the manufacturing condition to be transmitted to the solder printer X1 may be, for example, a mask cleaning frequency (N value, where the cleaning is performed once every N boards), or mask offset values being parameters for alignment between the mask and the board (the differences in the X-coordinate value, the Y-coordinate value, and the rotation angle from the current position). The manufacturing condition to be transmitted to the mounter X2 may be, for example, mounting coordinates of components (actual coordinates or offset values from the current position) or component sizes. The manufacturing condition to be transmitted to the reflow oven X3 may be a temperature profile of each layer in the oven (a temperature to be set or an offset value from the current temperature).

The optimal inspection criterion calculator 105 calculates the optimal inspection criterion for each of the inspection apparatuses Y1, Y2, Y3, and Y4 based on manufacturing data, inspection data, and inspection result data. More specifically, for example, the optimal inspection criterion calculator 105 calculates, through an inspection simulation, an inspection criterion that allows less false acceptance of defects or less overdetection (false rejection) than the current inspection criterion. When such an inspection criterion cannot be calculated, the current inspection criterion is determined to be the optimal inspection criterion.

The optimal inspection condition calculated in this manner is transmitted to the target inspection apparatus using a communicator (not shown), together with information (e.g., the name of the inspection program and its revision) identifying the inspection condition used to calculate the optimal inspection condition. The target inspection apparatus then determines whether to set the transmitted condition, as described later.

The inspection criterion to be transmitted herein may include all the information about the inspection criterion, or may be information specifying simply a change (a parameter item, a changed portion, or changed details) in the inspection condition used to calculate the optimal inspection condition.

The information to be transmitted varies depending on, for example, the relationship between the inspection program and the inspection criterion. In one example, a single inspection program may include all the inspection criteria valid in the program alone, and the inspection item and the inspection criterion may be defined for each inspection portion (e.g., for each piece number, each circuit number, or each terminal number). In this case, the above information indicates a change in the inspection criterion for each inspection item for the inspection portion for which the inspection criterion is to be changed. In another example, the inspection item and the inspection criterion may be defined for each component number. In this case, the above information indicates a change in the inspection criterion for each component number (for each terminal number, as appropriate) and each inspection item for which the inspection criterion is to be changed. In this case, a renewed inspection criterion set for the inspection apparatus involves a change in the inspection program.

In another example, the inspection criterion may be defined for each component number and may be used in multiple inspection programs. In other words, the inspection criterion may be managed outside the inspection program. In this case, the above information indicates a change in the inspection criterion for each component number (for each terminal number, as appropriate) and each inspection item for which the inspection criterion is to be changed. In this case, a renewed inspection criterion set for the inspection apparatus involves a change in data outside the inspection program, such as a component number library (e.g., a component shape, a component color, an inspection item, or an inspection criterion), rather than a change in the inspection program.

The optimal value reflection obtainer 106 (described later) obtains information about whether the manufacturing condition calculated by the optimal manufacturing condition calculator 104 has been reflected in the corresponding manufacturing apparatus, or information about whether the inspection criterion calculated by the optimal inspection criterion calculator 105 has been reflected in the corresponding inspection apparatus, or both. The display 107 outputs at least information obtained by the optimal value reflection obtainer 106.

The manufacturing implementers 211, 311, and 411 are functional units that each perform the manufacturing process in the corresponding manufacturing apparatus. The manufacturing implementer 211 in the solder printer X1 performs the process of printing a solder paste on lands on a printed board by screen printing. The manufacturing implementer 311 in the mounter X2 performs the process of picking up an electronic component to be mounted on the board and mounting the component on the solder paste on the target portion. The manufacturing implementer 411 in the reflow oven X3 performs the process of heating and melting the solder paste, and then cooling the solder paste to solder the electronic component on the board.

The determiners 212, 312, and 412 in the manufacturing apparatuses X1, X2, and X3 each determine whether the optimal manufacturing condition received using a communicator (not shown) is to be set as the renewed manufacturing condition for the corresponding manufacturing apparatus. More specifically, each determiner determines whether the manufacturing condition currently set for the manufacturing apparatus is identical to the manufacturing condition used to calculate the optimal manufacturing condition by the optimal manufacturing condition calculator 104. For example, the information identifying the manufacturing condition used to calculate the optimal manufacturing condition may be the name of a manufacturing program and its revision. In this case, the revision of the manufacturing program currently set for the manufacturing apparatus may be referred to for determining whether both the revisions are identical to each other.

When the manufacturing condition setter 213, 313, or 413 in the manufacturing apparatus X1, X2, or X3 determines that the optimal manufacturing condition is to be set as the renewed manufacturing condition for the manufacturing apparatus, the manufacturing condition setter 213, 313, or 413 sets the optimal manufacturing condition as the renewed manufacturing condition for the manufacturing apparatus. When determining that the optimal manufacturing condition is not to be set as the renewed manufacturing condition, the manufacturing condition setter 213, 313, or 413 suspends its determination about setting the optimal manufacturing condition for the manufacturing apparatus (or in other words, the manufacturing apparatus undergoes no change in the manufacturing condition).

The inspection implementers 221, 321, 421, and 431 are functional units that perform inspection in the inspection apparatuses Y1, Y2, Y3, and Y4 as described above.

The determiners 222, 322, 422, and 432 in the inspection apparatuses Y1, Y2, Y3, and Y4 each determine whether the optimal inspection criterion received using a communicator (not shown) is to be set as the renewed inspection criterion for the corresponding inspection apparatus. More specifically, for example, the determiners 222, 322, 422, and 432 each determine whether the inspection condition currently set for the inspection apparatus is identical to the inspection condition used to calculate the optimal inspection criterion, and, when both the conditions are identical to each other, determines that the optimal inspection criterion is to be set as the renewed inspection criterion for the inspection apparatus. For example, the information identifying the inspection condition used to calculate the optimal inspection criterion may be the name of an inspection program and its revision. In this case, the revision of the inspection program currently set for the inspection apparatus may be referred to for determining whether both the revisions are identical to each other. In another example, the information identifying the inspection condition used to calculate the optimal inspection criterion may be a revision of a component number library identifying the inspection criterion managed outside the inspection program. In this case, the revision of the component number library accessed by the inspection program may be referred to.

When the inspection criterion setter 223, 323, 423, or 433 in the inspection apparatus Y1, Y2, Y3, or Y4 determines that the optimal inspection criterion is to be set as the renewed inspection criterion for the inspection apparatus, the inspection criterion setter 223, 323, 423, or 433 sets the inspection criterion as the renewed inspection criterion for the inspection apparatus. When determining that the optimal inspection criterion is not to be set as the renewed inspection criterion, the inspection criterion setter 223, 323, 423, or 433 suspends its determination about setting the optimal inspection criterion for the inspection apparatus (or in other words, the inspection apparatus undergoes no change in the inspection criterion).

Each of the manufacturing apparatuses X1, X2, and X3 transmits, to the management apparatus 10, information about whether the optimal manufacturing condition has been set as the renewed manufacturing condition. Each of the inspection apparatuses Y1, Y2, Y3, and Y4 transmits, to the management apparatus 10, information about whether the optimal inspection criterion has been set as the renewed inspection criterion. The transmitted information is obtained by the optimal value reflection obtainer 106 in the management apparatus 10.

The information obtained by the optimal value reflection obtainer 106 is displayed by the display 107. More specifically, for example, the display 107 may display information indicating that the optimal manufacturing condition has been set as the renewed manufacturing condition for the manufacturing apparatus X1, X2, or X3, or information indicating that the optimal inspection criterion has been set as the renewed inspection criterion for the inspection apparatus Y1, Y2, Y3, or Y4. In contrast, when the optimal manufacturing condition or the optimal inspection criterion has not been set, the display 107 may display such information and also display an interface screen to receive a user instruction.

Calculating the optimal manufacturing condition, determining whether the optimal manufacturing condition is to be set, setting the optimal manufacturing condition, and obtaining and displaying the setting result described above may be performed individually for each of the manufacturing apparatuses X1, X2, and X3, or may be performed collectively. Similarly, calculating the optimal inspection criterion, determining whether the optimal inspection criterion is to be set, setting the optimal inspection criterion, and obtaining and displaying the setting result described above may be performed individually for each of the inspection apparatuses Y1, Y2, Y3, and Y4, or may be performed collectively.

(Example Processing)

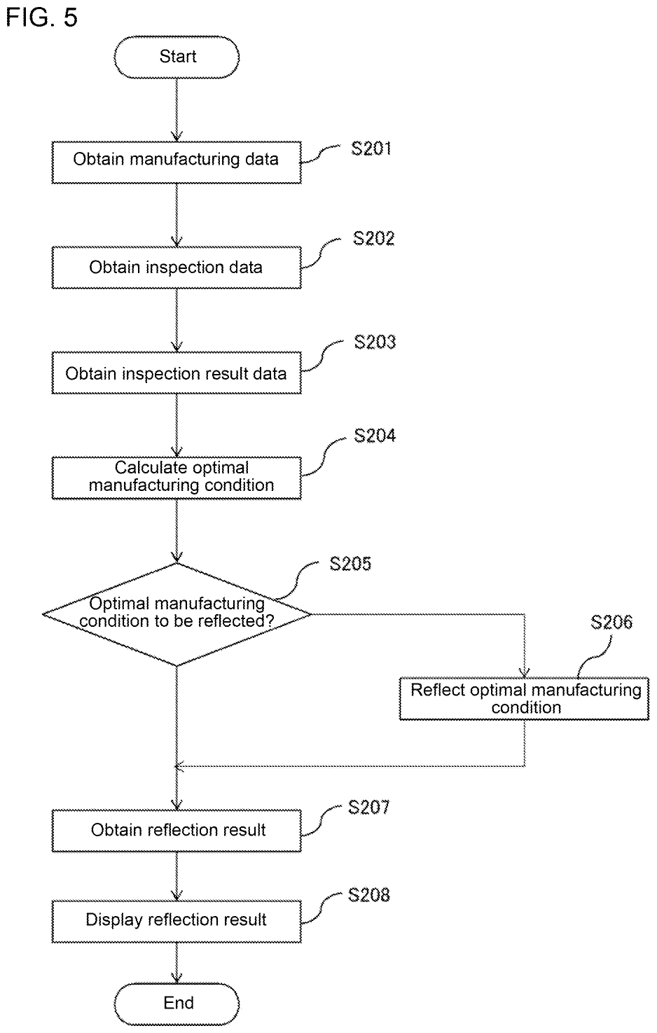

The processing for setting the optimal manufacturing condition for the mounter X2 in the production facility management system 1 will now be described with reference to FIG. 5. In response to a user instruction or at a predetermined timing, for example, the management apparatus 10 obtains manufacturing data with the manufacturing data obtainer 101 (S201), obtains inspection data with the inspection data obtainer 102 (S202), and obtains inspection result data with the inspection result obtainer 103 (S203).

The management apparatus 10 then calculates the optimal manufacturing condition with the optimal manufacturing condition calculator 104, and transmits, to the mounter X2, the calculated optimal manufacturing condition and information identifying the manufacturing condition (including mounting parameters) used to calculate the optimal manufacturing condition (S204).

The mounter X2 then determines, with the determiner 212, whether the calculated optimal manufacturing condition is to be set as the renewed manufacturing condition for the mounter X2 (S205). More specifically, when the manufacturing condition currently set for the mounter X2 is identical to the manufacturing condition used to calculate the optimal manufacturing condition transmitted in step S204, the mounter X2 determines that the optimal manufacturing condition is to be set as the renewed manufacturing condition.

When the mounter X2 determines that the optimal manufacturing condition is not to be set as the renewed manufacturing condition in step S205, such information is transmitted to the management apparatus 10, and the processing advances to step S207. In this case, the manufacturing condition used to calculate the optimal manufacturing condition has changed. Thus, setting the manufacturing condition calculated in step S204 for the mounter X2 can produce no effects or possibly produce opposite effects. Thus, the manufacturing condition is not set (changed).

When the mounter X2 determines that the optimal manufacturing condition is to be set as the renewed manufacturing condition in step S205, the mounter X2 sets, with the manufacturing condition setter 213, the optimal manufacturing condition calculated in step S204 as the renewed manufacturing condition for the mounter X2, and transmits such information to the management apparatus 10 (S206). The processing then advances to step S207.

The management apparatus 10 then obtains, with the optimal value reflection obtainer 106, information about whether the manufacturing condition calculated in step S204 has been reflected in the mounter X2 (S207), displays the information on the display 107 (S208), and ends the processing.

In the present embodiment, the manufacturing data obtainer 101, the inspection data obtainer 102, and the inspection result obtainer 103 correspond to a production data obtainer. The optimal manufacturing condition calculator 104 and the optimal inspection criterion calculator 105 correspond to an optimal value calculator. The determiners 212, 312, 412, 222, 322, 422, and 432 correspond to an optimal value setting determiner. The manufacturing condition setters 213, 313, and 413 and the inspection criterion setters 223, 323, 423, and 433 correspond to an optimal value setter.

The production facility management system 1 with the above structure can calculate the optimal manufacturing condition or the optimal inspection criterion for the manufacturing apparatus or the inspection apparatus installed in the production line, and can automatically set the optimized manufacturing condition or the optimized inspection criterion. The system can also automatically determine whether the optimized manufacturing condition or the optimized inspection criterion is appropriate. When determining that the optimized manufacturing condition or the optimized inspection criterion is inappropriate, the system does not use the optimized manufacturing condition or the optimized inspection criterion. When determining that the optimized manufacturing condition or the optimized inspection criterion is appropriate, the system reflects the optimized manufacturing condition or the optimized inspection criterion in the corresponding apparatus. This allows automatic optimization of the manufacturing condition for the manufacturing apparatus and the inspection criterion for the inspection apparatus. This greatly increases the efficiency of the production facility maintenance and the quality control.

<Modifications>

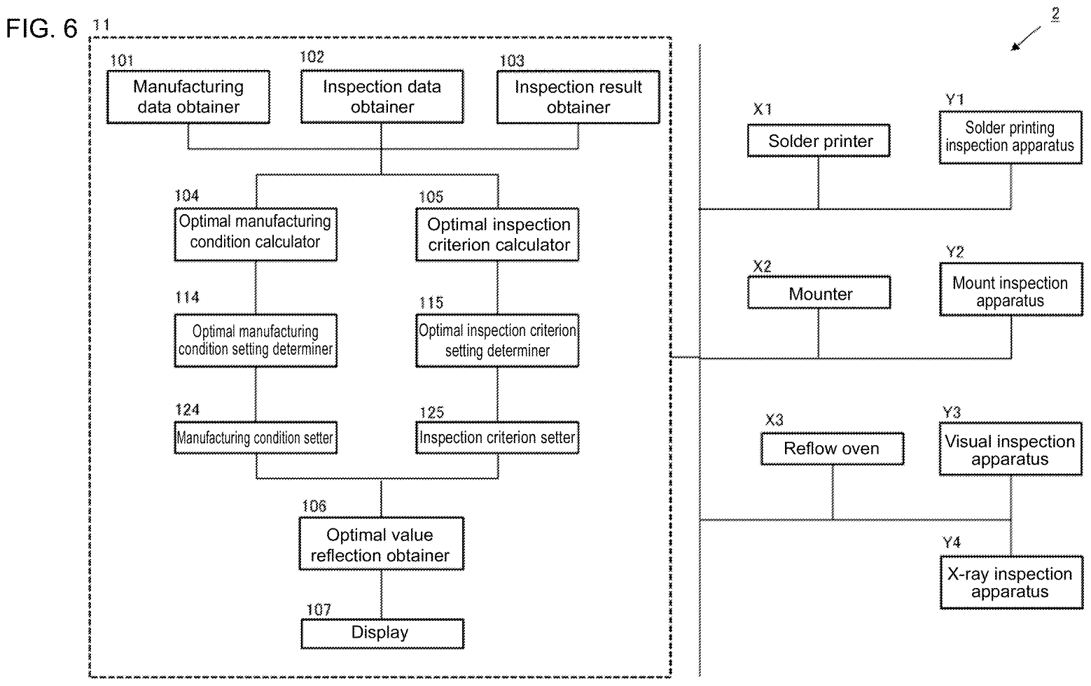

In the above embodiment, the manufacturing apparatuses and the inspection apparatuses each include the determiner and the setter. However, each apparatus may have another structure. FIG. 6 is a block diagram of a production facility management system 2 according to a modification of the embodiment. The production facility management system 2 according to the present modification includes many elements in common with the production facility management system 1. The elements (functions) that are the same or similar between these systems are indicated with the same reference numerals and are not described in detail.

Unlike the production facility management system 1, as shown in FIG. 6, the production facility management system 2 includes a management apparatus 11 including an optimal manufacturing condition setting determiner 114, a manufacturing condition setter 124, an optimal inspection criterion setting determiner 115, and an inspection criterion setter 125.

The optimal manufacturing condition setting determiner 114 obtains, from the optimal manufacturing condition calculator 104, the optimal manufacturing condition and information identifying the manufacturing condition used to calculate the optimal manufacturing condition. The optimal manufacturing condition setting determiner 114 also obtains, from each of the manufacturing apparatuses X1, X2, and X3, information identifying the manufacturing condition currently set for the corresponding apparatus. The optimal manufacturing condition setting determiner 114 refers to these pieces of information to determine whether the optimal manufacturing condition calculated by the optimal manufacturing condition calculator 104 is to be set as the renewed manufacturing condition for the target manufacturing apparatus. The determination is performed in the same manner as in the above embodiment, and is thus not described.

The manufacturing condition setter 124 reflects the optimal manufacturing condition in the target manufacturing apparatus when the optimal manufacturing condition setting determiner 114 determines that the optimal manufacturing condition is to be set as the renewed manufacturing condition for the target manufacturing apparatus. The reflection herein may be performed by, for example, transmitting information about the optimal manufacturing condition (that may be an instruction for a changed portion alone) to the manufacturing apparatus using a communication protocol, or by storing information about the optimal manufacturing condition into a shared folder on a communication network.

The optimal inspection criterion setting determiner 115 obtains, from the optimal inspection criterion calculator 105, the optimal inspection criterion and information identifying the inspection condition used to calculate the optimal inspection criterion. The optimal inspection criterion setting determiner 115 also obtains, from each of the inspection apparatuses Y1, Y2, Y3, and Y4, information identifying the inspection condition currently set for the corresponding apparatus. The optimal inspection criterion setting determiner 115 refers to these pieces of information to determine whether the optimal inspection criterion calculated by the optimal inspection criterion calculator 105 is to be set as the renewed inspection criterion for the target inspection apparatus. The determination is performed in the same manner as in the above embodiment, and is thus not described.

The inspection criterion setter 125 reflects the optimal inspection criterion in the target inspection apparatus when the optimal inspection criterion setting determiner 115 determines that the optimal inspection criterion is to be set as the renewed inspection criterion for the target inspection apparatus. The reflection herein may be performed by, for example, transmitting information about the optimal inspection criterion (that may be an instruction for a changed portion alone) to the inspection apparatus using a communication protocol, or by storing information about the optimal inspection criterion into a shared folder on a communication network.

In the structure in the above modification, the management apparatus 11 can both determine whether the optimal manufacturing condition or the optimal inspection criterion is to be reflected in the corresponding apparatus and set the optimal value.

<Others>

The above embodiments have been described by way of example, and the present invention is not limited to the specific embodiments described above. Various modifications may be made to the present invention within the scope of its technical idea. For example, the management system in the above embodiments optimizes both the manufacturing condition for the manufacturing apparatus and the inspection criterion for the inspection apparatus. However, the management system may optimize one of the manufacturing condition or the inspection criterion.

The system in the above embodiments determines whether the current production condition is identical to the production condition used to calculate the optimal value by determining whether the revisions of the program are identical to each other. However, the determination may be performed in another manner. For example, although the revision of the program is updated, the current condition can be identical to the condition used to calculate the optimal value for an item that undergoes a change when the optimal value is set. In this case, the current production condition may be determined identical to the production condition used to calculate the optimal value.

In the above embodiments, the calculated optimal value is determined to be set as the renewed manufacturing condition for the manufacturing apparatus when the current manufacturing condition is identical to the manufacturing condition used to calculate the optimal value. However, the determination may be performed in another manner. For example, when the manufacturing condition and the inspection condition used to calculate the optimal value are both identical to the current manufacturing condition and the current inspection condition, the calculated optimal manufacturing condition may be determined to be set as the renewed manufacturing condition. The same applies to the determination as to whether the optimal inspection criterion is to be set.

In the above embodiments, the manufacturing apparatus and the inspection apparatus in the production line are used for component mounting boards. However, the production facility according to one or more embodiments of the present invention may be used for other products as well.

<Appendixes>

A management system according to one aspect of the present invention is a management system (9; 1; 2) for a production facility (91; X1; X2; X3; 92; Y1; Y2; Y3; Y4) to produce a product, the management system (9; 1; 2) comprising:
a production data obtainer (931; 101; 932; 102; 933; 103) configured to obtain production data, the production data being information including a production condition for the product;
an optimal value calculator (934; 104; 105) configured to calculate an optimal production condition based on the production data, the optimal production condition being a production condition optimal to produce the product;
an optimal value setting determiner (922; 212; 312; 412; 222; 322; 422; 432; 114; 115) configured to perform determination as to whether the optimal production condition is to be set as a renewed production condition for the production facility; and an optimal value setter (923; 213; 313; 413; 223; 323; 423; 433; 124; 125) configured to set the optimal production condition for the production facility under a predetermined condition,
wherein the optimal value setting determiner determines that the optimal production condition is to be set as the renewed production condition for the production facility in response to the production condition at a time of the determination being identical to the production condition used to calculate the optimal production condition by the optimal value calculator.

A management apparatus according to another aspect of the present invention is a management apparatus (11) in a production facility (91; X1; X2; X3; 92; Y1; Y2; Y3; Y4) to produce a product, the management apparatus (11) comprising:
a production data obtainer (101; 102; 103) configured to obtain production data, the production data being information including a production condition for the product;
an optimal value calculator (104; 105) configured to calculate an optimal production condition based on the production data, the optimal production condition being a production condition optimal to produce the product;
an optimal value setting determiner (114; 115) configured to perform determination as to whether the optimal production condition is to be set as a renewed production condition for the production facility; and
an optimal value setter (124; 125) configured to set the optimal production condition for the production facility under a predetermined condition,
wherein the optimal value setting determiner determines that the optimal production condition is to be set as the renewed production condition for the production facility in response to the production condition at a time of the determination being identical to the production condition used to calculate the optimal production condition by the optimal value calculator.

A management method according to another aspect of the present invention is a management method for a production facility to produce a product, the management method comprising:
(S101; S201; S102; S202; S103; S203) obtaining production data, the production data being information including a production condition for the product;
(S104; S204) calculating an optimal production condition based on the production data, the optimal production condition being a production condition optimal to produce the product;
(S105; S205) performing determination as to whether the optimal production condition is to be set as a renewed production condition for the production facility; and (S106; S206) setting the optimal production condition for the production facility under a predetermined condition,
wherein performing the determination includes determining that the optimal production condition is to be set as the renewed production condition for the production facility in response to the production condition at a time of the determination being identical to the production condition used to calculate the optimal production condition.

### DESCRIPTION OF SYMBOLS

1, 2, 9 production facility management system
10, 11, 93 management apparatus
91, X2 mounter
92, Y2 mount inspection apparatus
X1 solder printer
X3 reflow oven
Y1 solder printing inspection apparatus
Y3 visual inspection apparatus
Y4 X-ray inspection apparatus

1. A management system for a production facility to produce a product, the management system comprising:
a production data obtainer configured to obtain production data, the production data being information including a production condition for the product;
an optimal value calculator configured to calculate an optimal production condition based on the production data, the optimal production condition being a production condition optimal to produce the product;
an optimal value setting determiner configured to perform determination as to whether the optimal production condition is to be set as a renewed production condition for the production facility; and
an optimal value setter configured to set the optimal production condition for the production facility under a predetermined condition,
wherein the optimal value setting determiner determines that the optimal production condition is to be set as the renewed production condition for the production facility in response to the production condition at a time of the determination being identical to the production condition used to calculate the optimal production condition by the optimal value calculator.

2. The management system according to claim 1, wherein
the optimal value setter sets the optimal production condition for the production facility in response to the optimal value setting determiner determining that the optimal production condition is to be set as the renewed production condition.

3. The management system according to claim 1, further comprising:
an output device configured to output at least a result of the determination; and
an input device,
wherein the optimal value setter sets the optimal production condition for the production facility in response to receiving, with the input device, an instruction to reflect the optimal production condition in the production facility.

4. The management system according to claim 1, further comprising:
an optimal value setting obtainer configured to obtain information about whether the optimal production condition is set for the production facility.

5. The management system according to claim 1, wherein
the production data includes information identifying a revision of a production program for information processing to operate the production facility, and
the optimal value setting determiner determines, in response to the revision of the production program at the time of the determination being identical to the revision of the production program used to calculate the optimal production condition by the optimal value calculator, that the production condition at the time of the determination is identical to the production condition used to calculate the optimal production condition by the optimal value calculator, and determines that the optimal production condition is to be set as the renewed production condition for the production facility.

6. The management system according to claim 5, wherein
the production data includes product element information and a revision of the product element information, the product element information being information about a product element included in the product, and
the information identifying the revision of the production program includes the revision of the product element information.

7. The management system according to claim 1, wherein
the production data includes product element information and information about a revision of the product element information, the product element information being information about a product element included in the product, and
the optimal value setting determiner determines, in response to the revision of the product element information about a specific product element in the product at the time of the determination being identical to the revision of the product element information about the specific product element in the product used to calculate the optimal production condition by the optimal value calculator, that the production condition at the time of the determination is identical to the production condition used to calculate the optimal production condition by the optimal value calculator, and determines that the optimal production condition is to be set as the renewed production condition for the production facility.

8. The management system according to claim 1, wherein
the production facility includes a manufacturing apparatus configured to manufacture the product,
the production data obtained by the production data obtainer includes manufacturing data being information including a manufacturing condition to manufacture the product with the manufacturing apparatus,
the optimal value calculator calculates at least an optimal manufacturing condition being a manufacturing condition optimal for manufacturing the product,
the optimal value setting determiner determines that the optimal manufacturing condition is to be set as a renewed manufacturing condition for the manufacturing apparatus in response to at least the manufacturing condition at the time of the determination being identical to the manufacturing condition used to calculate the optimal manufacturing condition by the optimal value calculator, and
the optimal value setter sets the optimal manufacturing condition for the manufacturing apparatus under the predetermined condition.

9. The management system according to claim 1, wherein
the production facility includes an inspection apparatus configured to perform inspection of the product,
the production data obtained by the production data obtainer includes inspection data including an inspection condition for the inspection, and inspection result data being information about a result of the inspection,
the optimal value calculator calculates at least an optimal inspection criterion being an inspection criterion optimal for the inspection,
the optimal value setting determiner determines that the optimal inspection criterion is to be set as a renewed inspection criterion for the inspection apparatus in response to at least the inspection condition at the time of the determination being identical to the inspection condition used to calculate the optimal inspection criterion by the optimal value calculator, and
the optimal value setter sets the optimal inspection criterion for the inspection apparatus under the predetermined condition.

10. The management system according to claim 1, wherein
the production facility includes a manufacturing apparatus configured to manufacture the product, and an inspection apparatus configured to perform inspection of the product,
the production data obtained by the production data obtainer includes manufacturing data being information including a manufacturing condition to manufacture the product with the manufacturing apparatus, inspection data including an inspection condition for the inspection, and inspection result data being information about a result of the inspection,
the optimal value calculator calculates, based on the manufacturing data, the inspection data, and the inspection result data, at least an optimal manufacturing condition being a manufacturing condition optimal for manufacturing the product,
the optimal value setting determiner determines that the optimal manufacturing condition is to be set as a renewed manufacturing condition for the manufacturing apparatus in response to the manufacturing condition and the inspection condition used to calculate the optimal manufacturing condition by the optimal value calculator being identical to the manufacturing condition and the inspection condition at the time of the determination, and
the optimal value setter sets the optimal manufacturing condition for the manufacturing apparatus under the predetermined condition.

11. The management system according to claim 1, wherein
the production facility includes a manufacturing apparatus configured to manufacture the product, and an inspection apparatus configured to perform inspection of the product,
the production data obtained by the production data obtainer includes manufacturing data being information including a manufacturing condition to manufacture the product with the manufacturing apparatus, inspection data including an inspection condition for the inspection, and inspection result data being information about a result of the inspection,
the optimal value calculator calculates, based on the manufacturing data, the inspection data, and the inspection result data, at least an optimal inspection criterion being an inspection criterion optimal for the inspection,
the optimal value setting determiner determines that the optimal inspection criterion is to be set as a renewed inspection criterion for the inspection apparatus in response to the manufacturing condition and the inspection condition used to calculate the optimal inspection criterion by the optimal value calculator being identical to the manufacturing condition and the inspection condition at the time of the determination, and
the optimal value setter sets the optimal inspection criterion for the inspection apparatus under the predetermined condition.

12. A management apparatus in a production facility to produce a product, the management apparatus comprising:
a production data obtainer configured to obtain production data, the production data being information including a production condition for the product;
an optimal value calculator configured to calculate an optimal production condition based on the production data, the optimal production condition being a production condition optimal to produce the product;
an optimal value setting determiner configured to perform determination as to whether the optimal production condition is to be set as a renewed production condition for the production facility; and
an optimal value setter configured to set the optimal production condition for the production facility under a predetermined condition,
wherein the optimal value setting determiner determines that the optimal production condition is to be set as the renewed production condition for the production facility in response to the production condition at a time of the determination being identical to the production condition used to calculate the optimal production condition by the optimal value calculator.

13. A management method for a production facility to produce a product, the management method comprising:
obtaining production data, the production data being information including a production condition for the product;
calculating an optimal production condition based on the production data, the optimal production condition being a production condition optimal to produce the product;
performing determination as to whether the optimal production condition is to be set as a renewed production condition for the production facility; and
setting the optimal production condition for the production facility under a predetermined condition,
wherein performing the determination includes determining that the optimal production condition is to be set as the renewed production condition for the production facility in response to the production condition at a time of the determination being identical to the production condition used to calculate the optimal production condition.

14. A non-transitory computer readable medium storing program for causing an information processing apparatus to perform operations included in the management method according to claim 13.
